(19) United States
(12) Patent Application Publication
(10) Pub. No.: US 2007/0223274 A1
(43) Pub. Date: Sep. 27, 2007

(54) Complex Memory Chip

(75) Inventors: Wen-Chieh Lee, Hsin-Chu City (TW); Hsiang-Cheng Ho, Hsin-Chu City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: MEMOCOM CORP., Hsin-Chu City (TW)

(21) Appl. No.: 11/689,760

(22) Filed: Mar. 22, 2007

(30) Foreign Application Priority Data
Mar. 27, 2006 (TW) 95110502
Mar. 5, 2007 (TW) 96107537

(51) Int. Cl. G11C 14/00; G11C 7/10; G11C 11/34

(52) U.S. Cl. 365/185.08; 365/189.03

(57) ABSTRACT

A complex memory chip is provided. The complex memory chip comprises a first pin, a second pin, a voltage generator, a flash memory, and a static random access memory (SRAM). The first pin is capable of transmitting a first voltage. The second pin is capable of transmitting a second voltage which is lower than the first voltage, so as to define a working voltage in association with the first voltage. The voltage generator generates a third voltage according to the first voltage, wherein the third voltage is greater than the first voltage. The flash memory and the SRAM operate under the working voltage. The flash memory erases data according to the third voltage.

This application claims the benefits of priorities based on Taiwan Patent Applications No. 095110502 filed on Mar. 27, 2006 and No. 096107537 filed on Mar. 5, 2007, in which the disclosures of the latter are incorporated herein by reference in their entirety.

### CROSS-REFERENCES TO RELATED APPLICATIONS

Not applicable.

### BACKGROUND OF THE INVENTION

1. Field of the Invention

The present invention relates to a complex memory chip; more specifically, the present invention relates to a complex memory chip without the needs of configuring a high voltage input pin and a particular operation status output pin.

2. Descriptions of the Related Art

In recent years, flash memories and static random access memories (SRAMs) have been developed rapidly. More manufacturers have started to assemble a flash memory and an SRAM together to form a complex memory chip to satisfy requirements of users.

However, both flash memories and the SRAMs have their own signal output and input pins. If the flash memory and the SRAM are assembled together directly without integrating these pins, the signal output/input pins of the complex memory chip will become complicated. Therefore, manufacturers have tried to integrate these signal output/input pins to reduce the number of pins.

A technique for integrating the address and data pins of flash memories and SRAMs to reduce the number of pins in the complex memory chip has been developed in the market. However, this kind of complex memory chip is not ideal. FIG. 1 is a schematic diagram illustrating a flash memory 1 of the complex memory chip of the prior art. The square 102 indicates a high voltage input pin Vpp connected to the outside of the complex memory chip. The high voltage input pin Vpp transmits a high voltage for the flash memory 1 to erase data. However, the aforementioned method for providing the high voltage will increase the number and types of voltage pins.

There is another complex memory chip that has been developed to integrate data and address pins of two different memories; however, the complex memory chip comprises a special operation status output pin to transmit an operation status signal of the memories. With this special operation status output pin, manufacturers are required to develop a corresponding communication protocol of data transmission for the special operation status output pin. As a result, the number of pins in the complex memory chip is increased, and therefore, this method does not address the original problem.

Although the aforementioned complex memories substantially integrate signal output/input pins, the high voltage input pin and the operation status output pin still have not been able to be integrated. Accordingly, manufacturers have had to develop corresponding hardware equipments and extra communication protocols, thereby, increasing the costs, as well as limiting the application of the memories. Thus, it is important to develop a complex pin without the additions of extra pins and communication protocols.

### SUMMARY OF THE INVENTION

One objective of this invention is to provide a complex memory chip comprising a first pin, a second pin, a voltage generator, a flash memory, and a static random access memory (SRAM). The first pin is configured to transmit a first voltage. The second pin is configured to transmit a second voltage which is lower than the first voltage, so as to define a working voltage in association with the first voltage. The voltage generator generates a third voltage according to the first voltage, wherein the third voltage is greater than the first voltage. The flash memory erases a data according to the third voltage. The flash memory and the SRAM are operated under the working voltage.

Another objective of this invention is to provide a complex memory chip comprising a first pin, a voltage pin, a data pin, a flash memory, and an SRAM. The first pin is configured to transmit a first voltage. The second pin is configured to transmit a second voltage lower than the first voltage, so as to define a working voltage in association with the first voltage. The flash memory transmits an operation status signal via the data pin. The flash memory and the SRAM are operated under the working voltage and transmit a data signal via the data pin.

The complex memory chip of the invention increases the working voltage to derive a high voltage and the high voltage is applied to the flash memory to erase data. Therefore, the complex memory chip of the invention does not need an extra high voltage input pin to receive the high voltage. Furthermore, the data operation status signal of the complex memory chip of the invention is transmitted via a general data pin, so there is no operation status output pin needed. Accordingly, because the complex memory chip of the invention does not need a pin for providing a high voltage nor a special operation status output pin, the number of pins is reduced.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 is a schematic diagram illustrating a flash memory of the prior art; and

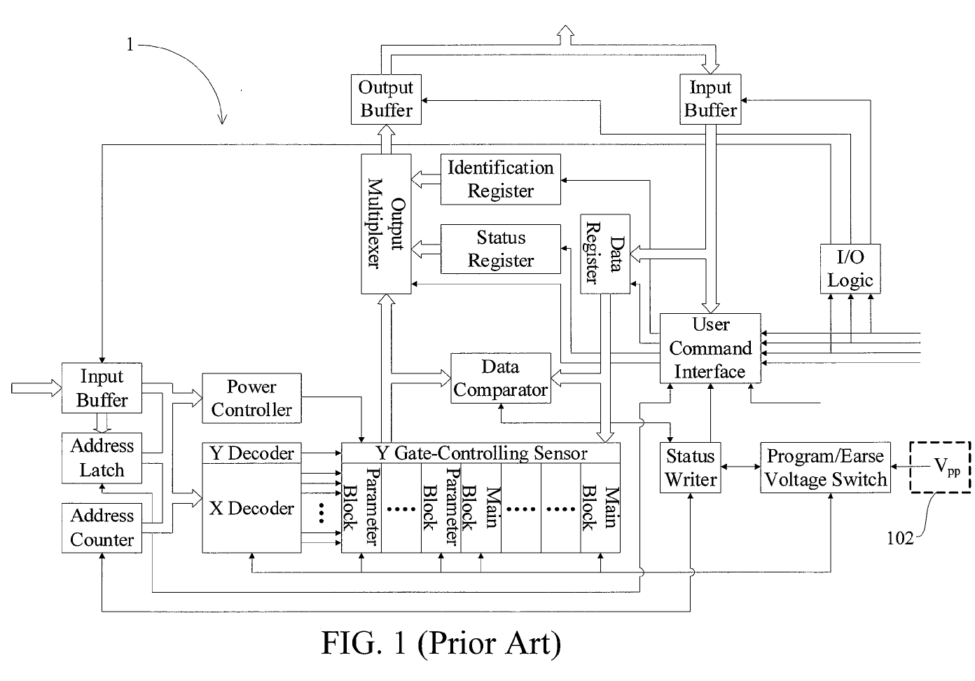

FIG. 2 is a schematic diagram illustrating a preferred embodiment of the present invention.

### DESCRIPTION OF THE PREFERRED EMBODIMENT

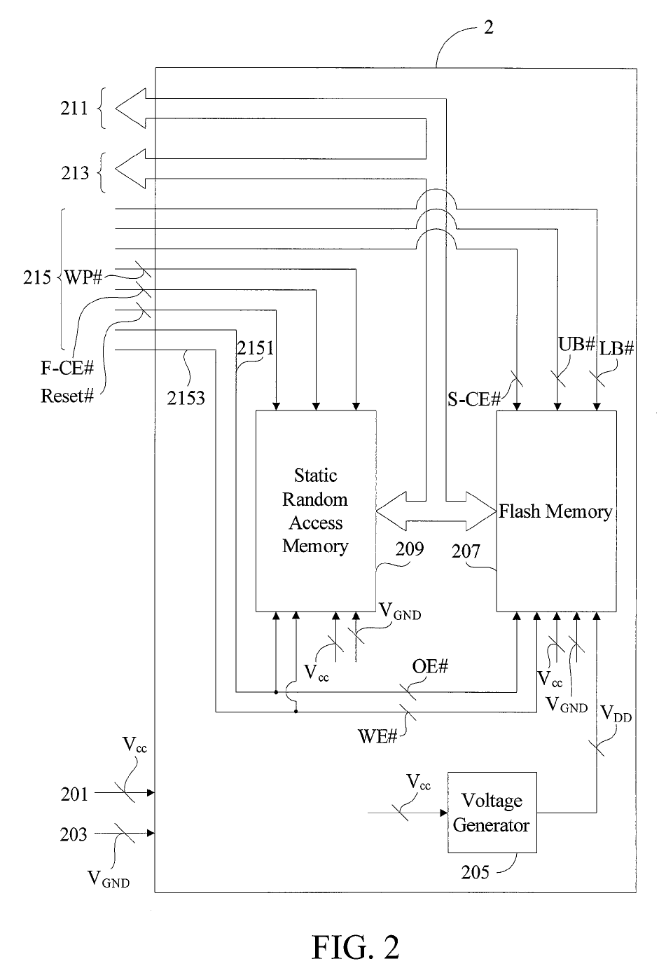

As shown in FIG. 2, a preferred embodiment of the present invention is a complex memory chip 2. The complex memory chip 2 comprises a first pin 201, a second pin 203, a voltage generator 205, a flash memory 207, an SRAM 209, an address pin set 211, a data pin set 213, and a plurality of control signal pins 215. The flash memory 207 may be applied to any kind of flash memory manufactured by any memory manufacturers in the market. In this preferred embodiment, the flash memory 207 is manufactured by Intel Corporation. The SRAM 209 may also be any kind of SRAM manufactured by any memory manufacturers. Furthermore, the SRAM 209 can be a pseudo static random access memory (PSRAM).

The first pin 201 is configured to transmit a first voltage V_{cc}. The second pin 203 is configured to transmit a second voltage V_{GND}. The second voltage V_{GND} is lower than the first voltage V_{cc}, so as to define a working voltage in association with the first voltage V_{cc}. The flash memory 207 and the SRAM 209 are operated under the working voltage. In this preferred embodiment, a voltage level of the second voltage V_{GND} is 0 volt, while the voltage level of the first voltage V_{cc} is the working voltage.

The voltage generator 205 receives the first voltage V_{cc} and generates a third voltage V_{DD} according to the first voltage V_{cc}. The third voltage V_{DD} is applied to the flash memory 207 to erase data. Therefore, the flash memory 207 can erase data without increasing the number of pins. Although the voltage generator 205 as shown in FIG. 2 is disposed in the complex memory chip 2, it can also be disposed in the flash memory 207. Those skilled in the art can easily understand that the invention does not limit the position of the voltage generator 205 by the explanation of the aforementioned descriptions, and thus, no unnecessary detail is given.

The address pin set 211 is used to transmit address signals of the flash memory 207 or address signals of the SRAM 209 as those of the general complex memory chip. Those skilled in the art can easily understand the operation of transmitting address signals, and thus, no unnecessary detail is given.

The data pin set 213 is used to transmit data signals of the flash memory 207 or data signals of the SRAM 209 as those of the general complex memory chip. In addition to transmitting data signals of the flash memory 207 and the SRAM 209, the data pin set 213 is also used to transmit an operation status signal of the flash memory 207. The operation status signal can be a reading status signal, a writing status signal, or a data erasing status signal. Therefore, the operation status signal of the flash memory 207 is transmitted without increasing the number of pins.

The control signal pins 215 are used to transmit various control signals used to control the flash memory 207 and the SRAM 209. The control signal pins 215 comprise an output-enabling pin 2151 and a write-enabling pin 2153. The flash memory 207 and the SRAM 209 share both the output-enabling pin 2151 and the write-enabling pin 2153. The output-enabling pin 2151 and the write-enabling pin 2153 transmit an output-enabling signal OE# and a write-enabling signal WE# respectively. The characteristics between the flash memory 207 and the SRAM 209 are different, so that other control signal pins can not be shared. For example, a lower byte enable signal LE#, an upper byte enable signal UE#, and an SRAM chip enable signal S-CE# for controlling the SRAM 209 can not be transmitted by only one control signal pin. In addition, a writing protect signal WP#, a flash memory chip enable signal F-CE#, and a reset signal Reset# for controlling the flash memory 207 can not be transmitted by only one control signal pin either. Therefore, the complex memory chip 2 still comprises control signal pins used to transmit the control signals as descried above.

The present invention does not limit the number or the functions of the control signal pins 215. That is, the number of pins can be increased to transmit different kinds of control signals. Those skilled in the art can easily understand the operations by the explanation of the aforementioned descriptions, and thus, no unnecessary detail is given.

Accordingly, the complex memory chip 2 of the invention increase first voltage V_{cc} to derive the high voltage, so the flash memory 207 can use the high voltage to erase data. The second voltage V_{GND} is inputted from the outside of the complex memory chip 2, so that the complex memory chip 2 of the invention does not need a high voltage input pin for the flash memory 207 to receive a high voltage. In addition, the data operation status of the flash memory 207 of the complex memory chip 2 is transmitted by general data pins so that the flash memory 207 of the complex memory chip 2 of the invention does not need an operation status signal pin.

Thus, the complex memory chip 2 of the invention reduces the number of pins needed. As a result, manufacturers will have less difficulty with layouts and will not need to add high voltage pins to transmit voltage. Furthermore, manufacturers will not need to develop a corresponding communication protocol of the data transmission for the special operation status output pin. Therefore, the problems of the prior art are solved.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A complex memory chip, comprising:
a first pin being configured to transmit a first voltage;
a second pin being configured to transmit a second voltage lower than the first voltage, so as to define a working voltage in association with the first voltage;
a voltage generator for generating a third voltage according to the first voltage, wherein the third voltage is greater than the first voltage;
a flash memory for erasing a data according to the third voltage; and
a static random access memory (SRAM);
wherein the flash memory and the SRAM are operated under the working voltage.

2. The complex memory chip of claim 1, wherein the voltage generator is disposed in the flash memory.

3. The complex memory chip of claim 1, further comprising an address pin, wherein the flash memory and the SRAM transmit an address signal via the address pin.

4. The complex memory chip of claim 3, wherein the address signal is one of an address signal of the flash memory and an address signal of the SRAM.

5. The complex memory chip of claim 1, further comprising a data pin, wherein the flash memory and the SRAM transmit a data signal via the data pin.

6. The complex memory chip of claim 5, wherein the data signal is one of a data signal of the flash memory and a data signal of the SRAM.

7. The complex memory chip of claim 5, wherein the flash memory has an operation status signal which is transmitted via the data pin.

8. The complex memory chip of claim 7, wherein the operation status signal is one of a reading status signal, a writing status signal, and a data erasing status signal.

9. The complex memory chip of claim 1, further comprising a control signal pin, wherein the flash memory and the SRAM transmit a control signal via the control signal pin.

10. The complex memory chip of claim 9, wherein the control signal pin is one of an output-enabling pin and a write-enabling pin.

11. A complex memory chip, comprising:
a first pin being configured to transmit a first voltage;
a second pin being configured to transmit a second voltage lower than the first voltage, so as to define a working voltage in association with the first voltage;
a data pin;
a flash memory for transmitting an operation status signal via the data pin; and
an SRAM;
wherein the flash memory and the SRAM are operated under the working voltage and transmit a data signal via the data pin.

12. The complex memory chip of claim 11, wherein the data signal is one of a data signal of the flash memory and a data signal of the SRAM.

13. The complex memory chip of claim 11, wherein the operation status signal of the flash memory is one of a reading status signal, a writing status signal, and a data erasing status signal.

14. The complex memory chip of claim 11, further comprising an address pin, wherein the flash memory and the SRAM transmit an address signal via the address pin.

15. The complex memory chip of claim 14, wherein the address signal is one of an address signal of the flash memory and an address signal of the SRAM

16. The complex memory chip of claim 11, further comprising a control signal pin, wherein the flash memory and the SRAM transmit a control signal via the control signal pin.

17. The complex memory chip of claim 16, wherein the control signal pin is one of an output-enabling pin and a write-enabling pin.
